(19) United States
(12) Patent Application Publication
(10) Pub. No.: US 2026/0079213 A1
(43) Pub. Date: Mar. 19, 2026

(54) SYSTEM AND METHOD FOR ESTIMATING LIFE OF BATTERY

(71) Applicant: SAMSUNG SDI CO., LTD., Yongin-si (KR)

(72) Inventors: Dongryul LEE, Yongin-si (KR); Junho JANG, Yongin-si (KR); Haemin KIM, Yongin-si (KR); Younghoon KO, Yongin-si (KR); Sangkoan YI, Yongin-si (KR); Yujin LEE, Yongin-si (KR); Youngwoong KWON, Yongin-si (KR)

(21) Appl. No.: 19/247,298

(22) Filed: Jun. 24, 2025

(30) Foreign Application Priority Data
Sep. 13, 2024 (KR) 10-2024-0126120

(51) Int. Cl. G01R 31/392; G01R 31/36; G01R 31/367

(52) U.S. Cl. CPC G01R 31/392; G01R 31/3648; G01R 31/367

(57) ABSTRACT

The present disclosure relates to a method of estimating a life of a battery including collecting life estimation data of a battery cell from a manufacturing process device of the battery cell, calculating slippage-related data based on the life estimation data, predicting a life of the battery cell based on the calculated slippage-related data, and estimating a life quality of the battery cell based on the predicted life.

### CROSS-REFERENCE TO RELATED APPLICATION

This application claims priority under 35 U.S.C § 119 to Korean Patent Application No. 10-2024-0126120, filed in the Korean Intellectual Property Office on Sep. 13, 2024, the entire contents of which are hereby incorporated by reference.

### BACKGROUND

### Field

Aspects of the present disclosure relate to a system and method for estimating the life of a battery.

### Description of the Related Art

When developing a battery or secondary battery, charging and discharging can be performed repetitively under conditions and for a time that are similar to the actual usage environment of the battery so that the life of the battery is guaranteed. In this way, by having the life of a battery (or the residual rate of charge capacity) measured, the long-term life of the battery can be predicted and the life of the battery can be estimated at the same time. However, this method of estimating the life of a battery takes a long time and is cumbersome. Accordingly, it is desirable to provide a method of predicting the life of a battery that can shorten the time for estimating the life of the battery and detect the failure of the battery at an early stage.

The above information disclosed in this Background section is for enhancement of understanding of the background of the present disclosure, and therefore, it may contain information that does not constitute related (or prior) art.

### SUMMARY

An aspect of the present disclosure provides a system and method for estimating the life of a battery and a method of operating that are quicker and less cumbersome than the prior art.

These and other aspects and features of the present disclosure will be described in or will be apparent from the following description of embodiments of the present disclosure.

According to an aspect of the present disclosure, a method of estimating a life of a battery may include collecting life estimation data of a battery cell from a manufacturing process device of the battery cell, calculating slippage-related data based on the life estimation data, predicting a life of the battery cell based on the calculated slippage-related data, and estimating a life quality of the battery cell based on the predicted life.

According to some embodiments, the predicting the life of the battery may include calculating cumulative slippage data based on the life estimation data of the battery, calculating a correlation between the cumulative slippage and a performance life of the battery, predicting the life of the battery based on the correlation, and estimating whether the battery cell is defective based on the predicted life of the battery cell.

According to some embodiments, the life estimation data may include voltage profile data on a capacity of the battery after 0 to 250 charge/discharge cycles.

According to some embodiments, the calculating the cumulative slippage data may include calculating cumulative capacity profile (CCP) data based on the life estimation data, and calculating the cumulative slippage based on the cumulative capacity profile (CCP) data.

According to some embodiments, calculating the correlation may include calculating a point of a sudden performance degradation of the battery based on the correlation between the cumulative slippage and the performance life of the battery.

According to some embodiments, each of the plurality of charge profiles may be a voltage profile corresponding to the capacity of the battery for one charge cycle, and each of the plurality of discharge profiles may be a voltage profile corresponding to the capacity of the battery for one discharge cycle.

According to some embodiments, calculating the cumulative slippage data may further include calculating a plurality of charge slippages and a plurality of discharge slippages based on the cumulative capacity profile (CCP) data.

According to some embodiments, each of the plurality of charge slippages may be an amount of change between a charge profile of a first charge cycle and a charge profile of a subsequent charge cycle, and each of the plurality of discharge slippages may be an amount of change between a discharge profile of a first discharge cycle and a discharge profile of a subsequent discharge cycle.

According to some embodiments, the calculating cumulative slippage data may further include calculating the cumulative slippage based on the plurality of charge slippages and the plurality of discharge slippages.

According to some embodiments, the cumulative slippage may be a sum of differences between each of the charge slippages and each of the discharge slippages.

According to some embodiments, predicting the life of the battery cell may include calculating a point of a sudden performance degradation of the battery based on the correlation between the cumulative slippage and the performance life of the battery.

According to some embodiments, the predicting the life of the battery cell may further include calculating a correlation between the cumulative slippage and the performance life of the battery using a linear regression model.

According to some embodiments, the predicting the life of the battery cell may further include predicting a state of health (SOH) of the battery according to charge/discharge cycles based on the point of a sudden performance degradation.

According to another aspect of the present disclosure, a system for estimating a life of a battery in accordance with some embodiments of the present disclosure may include a life estimation data collection device configured to collect life estimation data of a battery cell from a manufacturing process device that manufactures the battery cell, a life prediction device configured to calculate slippage-related data based on the life estimation data, predict a life of the battery cell based on the calculated slippage-related data, and estimate a life quality of the battery cell based on the predicted life.

According to some embodiments, the life prediction device may include at least one processor configured to read out and execute instructions stored in a memory to cause the life prediction device to function as a data generation module configured to generate cumulative slippage data based on the life estimation data of the battery, a slippage life analysis module configured to calculate a correlation between the cumulative slippage and a performance life of the battery, a life prediction module configured to predict the life of the battery based on the correlation, and a life estimation module configured to estimate whether the battery cell is defective based on the predicted life of the battery cell.

According to some embodiments, the life estimation data may include voltage profile data on a capacity of the battery after 0 to 250 charge/discharge cycles.

According to some embodiments, the data generation module may include a cumulative capacity profile calculation module configured to calculate cumulative capacity profile (CCP) data based on the life estimation data, and a slippage calculation module configured to calculate a cumulative slippage based on the cumulative capacity profile (CCP) data.

According to some embodiments, the cumulative capacity profile generation module may be configured to calculate the cumulative capacity profile (CCP) data based on a plurality of charge profiles and a plurality of discharge profiles extracted from the life estimation data.

According to some embodiments, the life prediction module may be configured to predict a state of health (SOH) of the battery corresponding to charge/discharge cycles based on the point of a sudden performance degradation.

According to some embodiments, the life estimation module may be configured to compare requirements for the battery cell received from the manufacturing process device with the predicted life of the battery cell, and estimate whether the battery cell is defective based on the comparison.

According to some embodiments of the present disclosure, the long-term life of a battery can be easily predicted based on charge and discharge data for the initial life data of the battery.

According to some embodiments of the present disclosure, the quality of the battery can be estimated at an early stage as the life of the battery can be predicted at an early stage. Based on the estimation result, the efficiency of battery manufacturing can be improved.

However, aspects and features of the present disclosure are not limited to those described above, and other aspects and features not mentioned will be clearly understood by a person skilled in the art from the detailed description, described below.

### BRIEF DESCRIPTION OF THE DRAWINGS

The following drawings attached to this specification illustrate embodiments of the present disclosure, and further describe aspects and features of the present disclosure together with the detailed description of the present disclosure. Thus, the present disclosure should not be construed as being limited to the drawings:

FIGS. 1 and 2 are block diagrams describing a life estimation system according to embodiments of the present disclosure.

FIG. 3 is a block diagram showing an information processing system used in the battery life estimation system according to embodiments of the present disclosure.

FIG. 4 is a block diagram describing the battery life prediction device according to embodiments of the present disclosure.

FIG. 5 is a block diagram describing the data generation module according to embodiments of the present disclosure.

FIGS. 6 and 7 are examples describing a CCP calculation module according to embodiments of the present disclosure.

FIGS. 8A and 8B are examples describing a slippage calculation module.

FIGS. 9 and 10 are examples describing the operation of the slippage life analysis module according to embodiments of the present disclosure.

FIG. 11 is an example describing the operation of the battery life estimation system according to other embodiments of the present disclosure.

FIG. 12 is a flowchart describing a life estimation method for a battery according to embodiments.

FIG. 13 is a flowchart describing the life prediction step of the life estimation method of FIG. 12.

### DETAILED DESCRIPTION

Hereinafter, embodiments of the present disclosure will be described, in detail, with reference to the accompanying drawings. The terms or words used in this specification and claims should not be construed as being limited to the usual or dictionary meaning and should be interpreted as meaning and concept consistent with the technical idea of the present disclosure based on the principle that the inventor can be his/her own lexicographer to appropriately define the concept of the term to explain his/her invention in the best way.

The embodiments described in this specification and the configurations shown in the drawings are only some of the embodiments of the present disclosure and do not represent all of the technical ideas, aspects, and features of the present disclosure. Accordingly, it should be understood that there may be various equivalents and modifications that can replace or modify the embodiments described herein at the time of filing this application.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. When phrases such as “at least one of A, B and C, “at least one of A, B or C,” “at least one selected from a group of A, B and C,” or “at least one selected from among A, B and C” are used to designate a list of elements A, B and C, the phrase may refer to any and all suitable combinations or a subset of A, B and C, such as A, B, C, A and B, A and C, B and C, or A and B and C. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112 (a) and 35 U.S.C. § 132 (a).

References to two compared elements, features, etc. as being “the same” may mean that they are “substantially the same”. Thus, the phrase “substantially the same” may include a case having a deviation that is considered low in the art, for example, a deviation of 5% or less. In addition, when a certain parameter is referred to as being uniform in a given region, it may mean that it is uniform in terms of an average.

Throughout the specification, unless otherwise stated, each element may be singular or plural.

Arranging an arbitrary element “above (or below)” or “on (under)” another element may mean that the arbitrary element may be disposed in contact with the upper (or lower) surface of the element, and another element may also be interposed between the element and the arbitrary element disposed on (or under) the element.

In addition, it will be understood that when a component is referred to as being “linked,” “coupled,” or “connected” to another component, the elements may be directly “coupled,” “linked” or “connected” to each other, or another component may be “interposed” between the components”.

Throughout the specification, when “A and/or B” is stated, it means A, B or A and B, unless otherwise stated. That is, “and/or” includes any or all combinations of a plurality of items enumerated. When “C to D” is stated, it means C or more and D or less, unless otherwise specified.

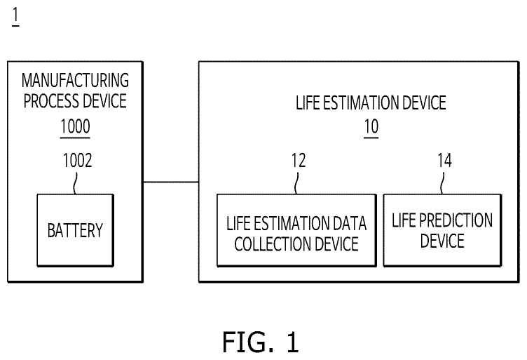

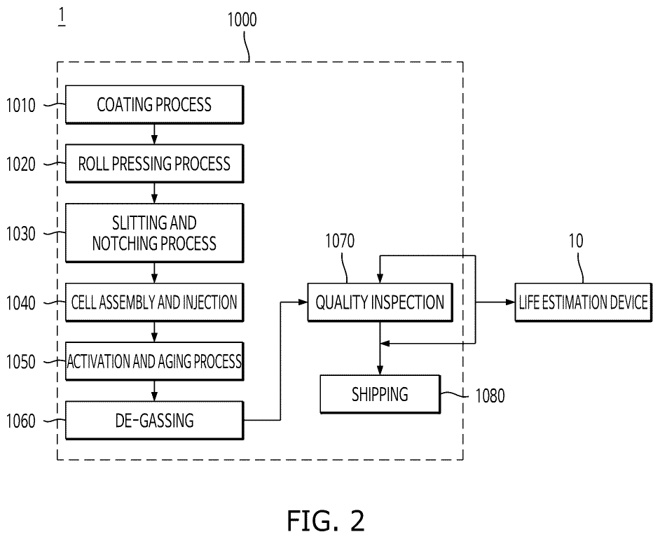

FIGS. 1 and 2 are block diagrams describing a life estimation system 1 according to some embodiments of the present disclosure.

Referring to FIG. 1, the life estimation system 1 may include a manufacturing process device 1000 and a life estimation device 10. Here, the manufacturing process device 1000 may be a device that manufactures battery cells.

The life estimation device 10 may include a life estimation data collection device 12 and a life prediction device 14.

The life estimation data collection device 12 may collect life estimation data of the battery 1002 from the manufacturing process device 1000 that manufactures the battery cells. For example, the life estimation data collection device 12 may collect life estimation data generated while the battery 1002 cells are repetitively charged and discharged by the manufacturing process device 1000. Here, the life estimation data may include voltage profile data on the charge capacity of the battery 1002. As a specific example, the life estimation data may be voltage profile data of the battery 1002 in the range of 0 to 250 charge/discharge cycles. In other embodiments, the life estimation data collection device 12 may include a charge/discharge module capable of performing charging/discharging on the battery 1002 manufactured by the manufacturing process device 1000, and a data collection module that collects life estimation data generated while repetitively performing charging and discharging on the battery 1002 cells.

The life prediction device 14 may calculate slippage-related data based on the life estimation data. Here, slippage refers to the amount of change in capacity in the cumulative capacity-voltage profile data. For example, a charge slippage may refer to the amount of change in charge capacity in the cumulative capacity-voltage profile data, and a discharge slippage may refer to the amount of change in discharge capacity in the cumulative capacity-voltage profile data.

The life prediction device 14 may predict the life of the battery 1002 based on the slippage-related data. More specifically, the life prediction device 14 may predict the life of the battery 1002 based on the correlation between the slippage-related data including the cumulative slippage and the deterioration tendency of the battery 1002. For example, the deterioration tendency may include, but is not limited to, a point of a sudden decline or a point of EOL (end of life) of the battery 1002. The deterioration tendency may include characteristics indicative of a deterioration tendency according to the life of the battery 1002.

The correlation between the cumulative slippage and the performance life of the battery 1002 may be calculated using a linear regression model technique. Further, the life prediction device 14 may predict the state of health (SOH) of the battery 1002 according to the charge/discharge cycle based on the correlation. The life predicted by the life prediction device 14 may be used to estimate the life quality of the battery 1002.

As described above, the battery life estimation system 1 according to embodiments of the present disclosure can easily predict the long-term life of a battery based on the initial life data of the battery.

According to embodiments of the present disclosure, the quality of the battery cells can be estimated at an early stage as the life of the battery can be predicted. Based on the estimation result, the efficiency of battery manufacturing can be improved.

Referring to FIG. 2, the life estimation system 1 may predict the life of a battery cell using the life estimation device 10 linked with the manufacturing process device 1000. Thereafter, the life estimation system 1 may estimate the quality of the battery cell based on the predicted life. For example, life estimation data of the battery cell manufactured by the manufacturing process device 1000 may be input into the life estimation device 10, and based on the input, the life estimation device 10 may predict the life of the battery.

In some embodiments, the manufacturing process device 1000 may manufacture a battery cell based on the design specifications of the battery cell. Further, the manufacturing process device 1000 may inspect the quality of the manufactured battery cell based on the life prediction result and life estimation result calculated by the life estimation device 10.

The manufacturing process device 1000 may execute a battery cell manufacturing process and a quality inspection process. For example, the battery cell manufacturing process may include a coating process 1010, a roll pressing process 1020, a slitting and notching process 1030, cell assembly and injection 1040, an activation and aging process 1050, and a de-gassing process 1060. The battery cell quality inspection process also may include quality inspection 1070 and shipping 1080.

The coating process 1010 may be a process of coating a slurry containing an active material of a positive or negative electrode on a current collector of the battery cell. The roll pressing process 1020 may include rolling the electrodes of the battery cell coated with active materials to flatten the electrodes. The slitting and notching process 1030 may cut the electrodes to fit the size of the battery cells, form and process the electrode tabs, etc. The cell assembly and injection 1040 may include injecting an electrolyte into the battery cells after assembling the battery cells. The activation and aging process 1050 may include stabilizing the battery cell by charging and discharging the battery cell. The de-gassing 1060 may remove gas inside the battery cell that was generated in the activation and aging process 1050.

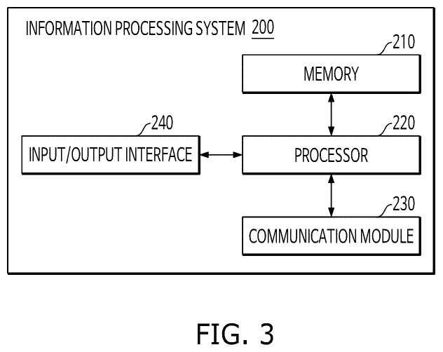

In some embodiments, if a new battery cell is developed according to a customer's requirements, the life estimation device 10 may receive life estimation data of the battery cell. Further, the battery cell may be manufactured by the manufacturing process device 1000 according to the specifications. Upon executing the quality inspection 1070 of the battery cell, the manufacturing process device 1000 may transfer the life estimation data of the battery cell to the life estimation device 10. The life estimation device 10 may predict the life of the battery cell based on the specifications of the battery cell and/or the life estimation data of the battery cell. The life estimation device 10 may also estimate the quality of the battery cell. Then, the life estimation device 10 may transfer the predicted life and quality estimation results of the battery cell to the manufacturing process device 1000. Accordingly, the manufacturing process device 1000 may determine whether the predicted life of the battery cell satisfies the customer's requirements in the quality inspection 1070. If the battery cell does not satisfy the customer's requirements, the manufacturing process device 1000 may not ship the battery cell (1080). On the other hand, if the battery cell satisfies the customer's requirements, the manufacturing process device 1000 may ship the battery cell (1080). A specific example of the life estimation system 1 will be described in detail with reference to FIGS. 3 to 5.

FIG. 3 is a block diagram showing an information processing system 200 used in the battery life estimation system 1 according to embodiments of the present disclosure.

Referring to FIG. 3, the information processing system 200 may correspond to at least one or more of the battery life estimation device 10 and the life prediction device 14 shown in FIG. 1. The information processing system 200 may include a memory 210, a processor 220, a communication module 230, and an input/output interface 240. The information processing system 200 may be configured to communicate information and/or data over a network using the communication module 230. In some embodiments, the information processing system 200 include at least one device that includes the memory 210, the processor 220, the communication module 230, and the input/output interface 240.

The memory 210 may include any non-transitory computer-readable recording medium. In some embodiments, the memory 210 may include a permanent mass storage device, such as read-only memory (ROM), a disk drive, a solid-state drive (SSDs), flash memory, etc. As another example, the permanent mass storage device, such as ROM, SSD, flash memory, a disk drive, etc., may be included in the information processing system 200 as a separate persistent storage device distinct from the memory 210. Further, the memory 210 may store software components including an operating system and at least one program code, such as code for implementing a slippage life analysis module and a life prediction module installed and run in the information processing system 200.

These software components may be loaded from a computer-readable recording medium separate from the memory 210. Such a separate computer-readable recording medium may include a recording medium directly connectable to the information processing system 200, and may include, for example, computer-readable recording media such as floppy drives, disks, tapes, DVD/CD-ROM drives, memory cards, etc. As another example, the software components may be loaded into the memory 210 via the communication module 230 rather than computer-readable recording media. For example, at least one program may be loaded onto the memory 210 based on a computer program (e.g., programs for implementing a slippage life analysis module and a life prediction module, etc.) installed by files provided via the communication module 230 by developers or a file distribution system that distributes installation files of an application.

The processor 220 may be configured to process commands of computer programs by performing basic arithmetic, logic, and input/output operations. The commands may be provided to a user terminal (not shown) or another external system by the memory 210 or the communication module 230. For example, the processor 220 may collect life estimation data of the battery from one or more manufacturing facilities, generate cumulative slippage data based on the life estimation data, calculate a correlation between the cumulative slippage and the performance life of the battery, and then predict the life of the battery based on the correlation.

The communication module 230 may provide a configuration or function for the user terminal (not shown) and the information processing system 200 to communicate with each other via a network. The communication module 230 also may provide a configuration or function for the information processing system 200 to communicate with an external system such a manufacturing facility for the battery, a separate cloud system, etc. In some embodiments, control signals, commands, data, etc., provided under the control of the processor 220 of the information processing system 200 may be transmitted to the user terminal and/or the external system by way of the communication module 230 and the network via the communication module of the user terminal and/or the external system. For example, the predicted life information of the battery, etc., generated by the information processing system 200 may be transmitted to the user terminal and/or the external system by way of the communication module 230 and the network via the communication module of the user terminal and/or the external system. Further, the user terminal and/or the external system that has received the predicted battery life information may output the received information via a display device.

The input/output interface 240 of the information processing system 200 may be a means for interfacing with devices (not shown) for input or output that may be connected to the information processing system 200 or that the information processing system 200 may include. In FIG. 3, the input/output interface 240 is shown as an element configured separate from the processor 220. But the present disclosure is not limited thereto, and the input/output interface 240 may be configured to be included in the processor 220. The information processing system 200 may include more components than those in FIG. 3.

The processor 220 of the information processing system 200 may be configured to manage, process, and/or store information and/or data received from a plurality of user terminals and/or a plurality of external systems. According to some embodiments, the processor 220 may receive the life estimation data of the battery, etc., from the user terminal and/or the external system. The processor 220 may calculate a cumulative slippage based on the life estimation data of the battery, predict the life of the battery based on the calculated cumulative slippage, and then output the corresponding life prediction information, etc., via a display device connected to the information processing system 200.

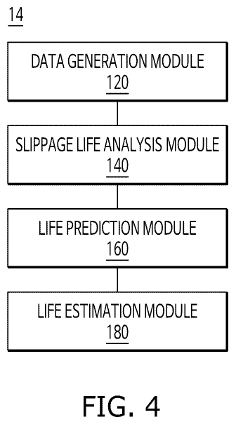

FIG. 4 is a block diagram describing the battery life prediction device 14 according to some embodiments of the present disclosure.

Referring to FIG. 4, the life prediction device 16 may include a data generation module 120, a slippage life analysis module 140, a life prediction module 160, and a life estimation module 180.

In some embodiments, the data generation module 120 may generate cumulative slippage data based on the life estimation data of the battery. Here, the cumulative slippage may be calculated based on cumulative capacity profile (CCP) data. The cumulative capacity profile (CCP) data may be obtained by accumulating a plurality of charge capacity-voltage profiles and a plurality of discharge capacity-voltage profiles.

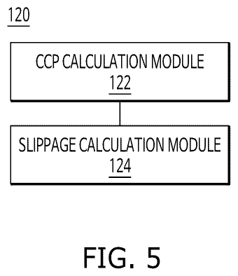

The specific configuration of the data generation module 120 will be described in detail with reference to FIGS. 5 to 8b.

In some embodiments, the slippage life analysis module 140 may calculate a correlation between the cumulative slippage and the deterioration tendency of the battery. Here, the deterioration tendency may include a point of a sudden decline or a point of EOL (end of life) of the battery 12. The point of a sudden decline may refer to a cycle point at which the slope of the state of health (SOH) with respect to the charge capacity of the battery decreases rapidly due to rapid deterioration of the battery, etc. Based on the correlation described above, the life analysis module 140 may calculate the correlation between the cumulative slippage and the performance life of the battery.

The slippage life analysis module 140 may calculate a correlation between the cumulative slippage and the performance life of the battery using a linear regression model technique. However, the present disclosure is not limited thereto. For example, the performance life of the battery may be included in the life estimation data of the battery. Here, the performance life may refer to a life cycle when the state of health (SOH) of the battery is between 75% and 85%. Preferably, the performance life may be, but is not limited to, a life cycle when the state of health (SOH) of the battery is 80%. Here, the point at which the state of health (SOH) of the battery is 80% may be an EOL point of the battery.

In some embodiments, the cumulative slippage may be calculated from the accumulated charge slippage and discharge slippage when the number of life cycles of the battery is in the range of 0 to 250. Preferably, the cumulative slippage may be calculated in the range of 0 to 100 life cycles of the battery. However, the present disclosure is not limited thereto.

In some embodiments, the cumulative slippage may have linearity with respect to the performance life, and the slippage analysis module 140 may calculate a correlation having such linearity. Accordingly, the slippage analysis module 140 may calculate a performance life or state of health corresponding to a particular cumulative slippage of the battery based on the correlation having such linearity.

In some embodiments, the slippage analysis module 140 may calculate a correlation according to a linear regression model in advance based on data on the cumulative slippage and performance life of a plurality of batteries. Then, the slippage analysis module 140 may store the calculated correlation calculated, and then calculate a correlation between the cumulative slippage and the performance life of the battery.

The life prediction module 160 may predict the state of health (SOH) of the battery according to the charge/discharge cycle based on the correlation between the cumulative slippage and the performance life calculated by the life analysis module 140. The life estimation module 180 may estimate whether the battery cell is defective based on the predicted life of the battery cell. For example, the life estimation module 180 may estimate whether the battery cell is defective by comparing the requirements for the battery cell received from the manufacturing process device 1000 of FIG. 2 with the predicted life of the battery cell.

As described above, the battery life estimation system 1 according to embodiments of the present disclosure can easily predict the long-term life of a battery based on the cumulative slippage, which is the initial life data of the battery. Further, the battery life estimation system 1 can predict the life of the battery at an early stage and can thereby estimate the quality of the battery at an early stage.

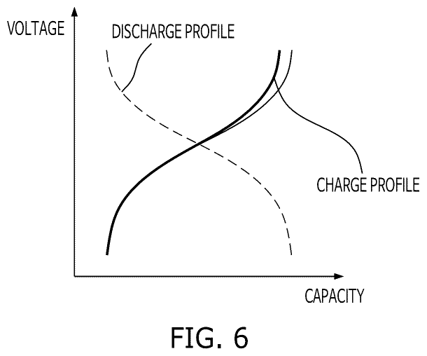

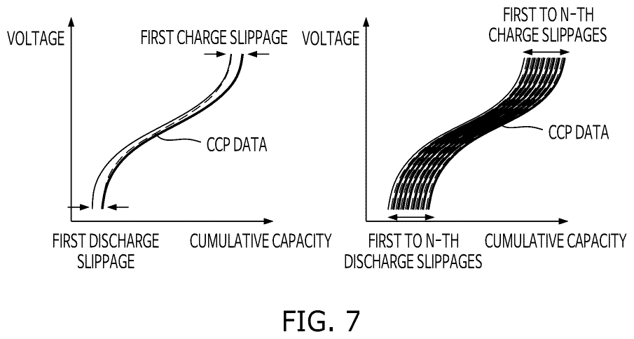

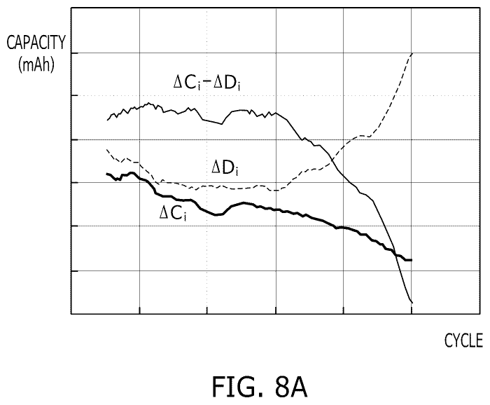

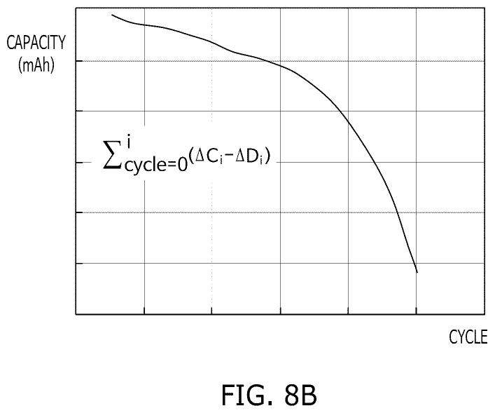

FIG. 5 is a block diagram describing the data generation module 120 according to embodiments of the present disclosure. FIGS. 6 and 7 are examples describing a CCP calculation module 122 according to some embodiments of the present disclosure, and FIGS. 8a and 8b are examples describing a slippage calculation module 124.

Referring to FIG. 5, the data generation module 120 may include the CCP calculation module 122 and the slippage calculation module 124. In some embodiments, the CCP calculation module 122 may calculate cumulative capacity profile (CCP) data based on the life estimation data. For example, referring to FIG. 6, a plurality of charge profiles and discharge profiles showing changes in charge and discharge voltages according to changes in the charge capacity of the battery may be measured. Of these, each of the plurality of charge profiles may be a voltage profile according to the capacity of the battery for one charge cycle. Further, each of the plurality of discharge profiles may be a voltage profile according to the capacity of the battery for one discharge cycle.

Referring to FIG. 7, the CCP calculation module 122 may calculate cumulative capacity profile (CCP) data based on the plurality of charge profiles and the plurality of discharge profiles extracted from the life estimation data. Further, the slippage calculation module 124 may calculate a cumulative slippage based on the cumulative capacity profile (CCP) data.

The slippage calculation module 124 may calculate a plurality of charge slippages and a plurality of discharge slippages based on the cumulative capacity profile (CCP) data. Referring to FIGS. 8a and 8b, each of the plurality of charge slippages may be the amount of change between the charge profile of a first charge cycle and the charge profile of a subsequent cycle of the first charge cycle. That is, the i-th charge slippage ΔC_i may be the amount of change between the (i+1)th charge profile C_i+1 and the i-th charge profile C_i. Further, each of the plurality of discharge slippages may be the amount of change between the discharge profile of a first discharge cycle and the discharge profile of a subsequent cycle of the first discharge cycle. That is, the i-th discharge slippage ΔD_i may be the amount of change between the (i+1)th discharge profile D_i+1 and the i-th discharge profile D_i.

The slippage calculation module 124 may calculate the cumulative slippage based on the plurality of charge slippages ΔC and the plurality of discharge slippages ΔD. Here, the cumulative slippage may be the sum of the difference values ΔC−ΔD between each of the plurality of charge slippages ΔC and each of the plurality of discharge slippages ΔD. That is, the cumulative slippage may be expressed as:

$${\sum }_{cycle = 0}^{i} ( Δ C\_i - Δ D\_i )$$

The slippage calculation module 124 may use the life estimation data when the number of life cycles of the battery is in the range of 0 to 250. Accordingly, the slippage calculation module 124 may calculate the cumulative slippage in the range of 0 to 250 life cycles.

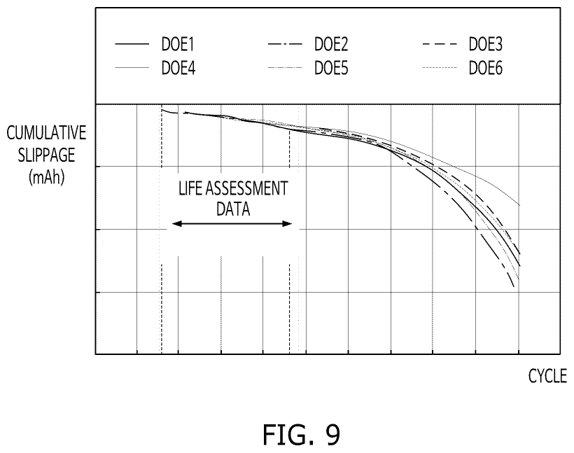

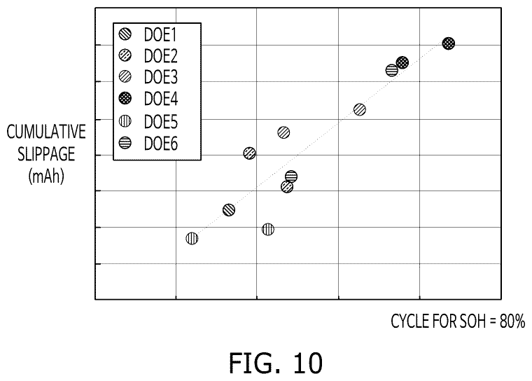

FIGS. 9 and 10 are examples describing the operation of the slippage life analysis module 140 according to embodiments of the present disclosure.

Referring to FIG. 9, the data generation module 120 may calculate a cumulative slippage according to a predetermined number of life cycles of the battery. Here, the predetermined number of life cycles may be 70 to 250, which is the range of the initial life cycles of the battery. In this case, the cumulative slippage may be calculated based on the initial life data of the battery. FIG. 9 shows a plurality of design of experiments (DOE), and each DOE represents a cumulative slippage calculated for the life estimation data in the range of 70 to 250 life cycles of different experimental batteries. The data generation module 120 may transfer the cumulative slippage calculation to the life analysis module 140. Further, the life analysis module 140 may receive the life estimation data, and the life analysis module 140 may extract a performance life from the life estimation data. Here, the performance life may be an initial life cycle when the state of health (SOH) of the battery is 80%. Moreover, the life analysis module 140 may calculate a correlation between the cumulative slippage and the performance life. The point at which the state of health (SOH) of the battery is 80% may be an EOL point of the battery.

Referring to FIG. 10, the life analysis module 140 may calculate a correlation between the cumulative slippage and the performance life. FIG. 10 shows the correlation calculated by the life analysis module 140 based on the linearity between the cumulative slippage and the performance life calculated for a plurality of experimental data DOE1 to DOE6. Here, the performance life may be a life cycle when the state of health (SOH) is 80%. However, such a performance life is merely one example and the present disclosure is not limited thereto. Then, the life analysis module 140 may transfer the correlation between the calculated cumulative slippage and the performance life to the life prediction module 160. Then, the life prediction module 160 may predict the state of health (SOH) according to the charge/discharge cycle of the battery based on the correlation between the cumulative slippage and the performance life calculated by the life analysis module 140.

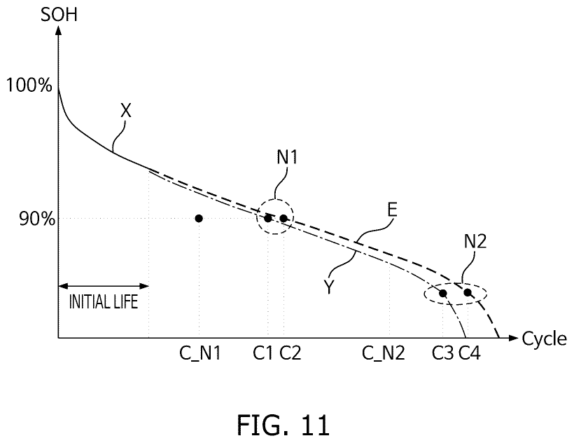

FIG. 11 shows the operation of the battery life estimation system 1 according to other embodiments of the present disclosure.

Referring to FIG. 11, the curve X in the graph may be life estimation data of the battery cell. For example, the initial life data of the battery cell may be a state of health (SOH) in the range of 1 to 100 life cycles. However, the present disclosure is not limited thereto.

The curve Y in the graph shown may be the life of the battery cell predicted by the life estimation device 10 according to embodiments of the present disclosure. The curve E may be the life of the battery cell as measured through actual experiments.

In specific example, a customer who has requested the development of a battery cell may require that the state of health (SOH) of the corresponding battery be 90% when the life cycle of the battery cell is C_N1. Further, the customer may require that the life cycle exhibiting a sudden drop in the life state of the battery cell be C_N2. That is, the customer may require that the life cycle be C_N1 when the state of health (SOH) of the battery cell is 90%, and the life cycle be C_N2 when the battery cell exhibits a sudden drop.

The life estimation system 1 may estimate the customer's requirements by using the life estimation device 10 during quality inspection.

Referring to FIG. 11, it can be confirmed with reference to the curve Y, which represents the output life state of the life estimation device 10, that the life cycle of the battery cell is C1 when the state of health (SOH) of the battery cell is 90% (N1). In contrast, referring to the curve E, which is an actual experimental curve, it can be confirmed that the life cycle of the battery cell is C2. That is, it can be confirmed that the manufactured battery cell exhibits a better life state than the customer's requirements. Further, it can be confirmed that the result obtained by predicting the life of the battery cell by the life estimation device 10 is similar to the actual measured life of the battery. That is, it can be confirmed through the graph the prediction accuracy of the life estimation device 10 is 90% or greater.

Moreover, referring to the curve Y, it can be confirmed that the life cycle of the battery cell is C3 when a sudden drop (N2) occurs in the battery cell. In contrast, referring to the curve E, it can be confirmed that the life cycle of the battery cell is C4. That is, it can be confirmed that the manufactured battery cell exhibits a better life state than the customer's requirements. Further, it can be confirmed using the graph shown that the result obtained by predicting the life of the battery cell by the life estimation device 10 is similar to the actual measured life of the battery. Accordingly, the life estimation device 10 may estimate the life quality of the battery cell as normal.

As described above, the battery life estimation system 1 according to some embodiments of the present disclosure can predict the long-term life of the battery by analyzing the life of the battery at an early stage based on the initial life data of the battery. Further, the result data and life estimation data for the life prediction of the battery of the life estimation system 1 can be use in the development and manufacturing process of the battery cell.

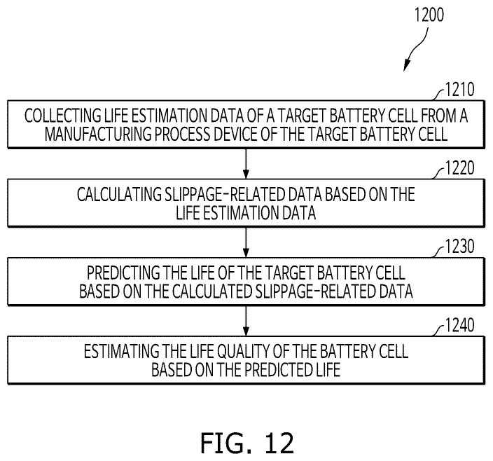

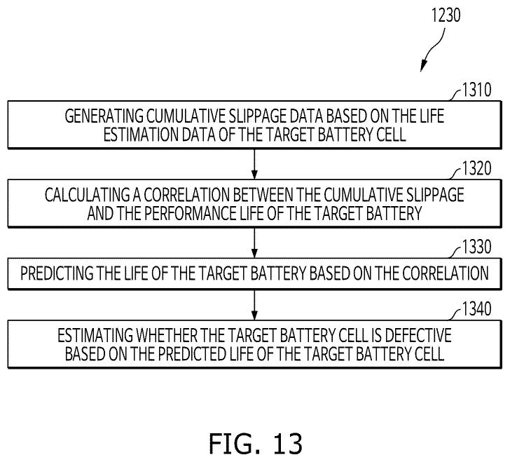

FIGS. 12 and 13 are flowcharts showing a life estimation method 1200 for a battery according to embodiments of the present disclosure.

Referring to FIG. 12, the life estimation method 1200 may be executed by the life estimation system 1 of FIG. 1.

The life estimation method 1200 may begin by collecting life estimation data of a battery cell from a manufacturing process device of the battery cell (1210). For example, the life estimation data collection device 12 of FIG. 1 may collect life estimation data of the battery cell from the manufacturing process device of the battery cell. Here, the life estimation data may include voltage profile data on the capacity of the battery that has been subjected to 0 to 250 charge/discharge cycles. Further, slippage-related data may be calculated based on the life estimation data (1220). For example, the life prediction device 14 of FIG. 1 may calculate the slippage-related data based on the life estimation data.

Accordingly, the life of the battery cell may be predicted based on the slippage-related data calculated (1230). For example, the life prediction device 14 may predict the life of the battery cell based on the calculated slippage-related data.

Then, the life quality of the battery cell may be estimated based on the predicted life (1240). For example, the life prediction device 14 may estimate the life quality of the battery cell based on the predicted life.

FIG. 13 is a flowchart of the life prediction step 1230 of the life estimation method 1200 of FIG. 12.

Referring to FIG. 13, the life estimation method 1200 may be executed by the life prediction device 14 of FIG. 4.

Cumulative slippage data may be calculated based on the life estimation data of the battery (1310). For example, the data generation module of FIG. 4 may calculate the cumulative slippage data. According to some embodiments, the calculating the cumulative slippage data (1310) may include calculating cumulative capacity profile (CCP) data based on the life estimation data and calculating a cumulative slippage based on the cumulative capacity profile (CCP) data.

Then, a correlation between the cumulative slippage and the performance life of the battery may be calculated (1320). For example, the life analysis module 140 of FIG. 4 may calculate the correlation between the cumulative slippage and the performance life.

According to embodiments, the calculating the correlation (1320) may include calculating a correlation between the cumulative slippage and a deterioration tendency of the battery. In other embodiments, calculating the correlation (1320) may include calculating a correlation between the cumulative slippage and the performance life of the battery using a linear regression model technique.

Accordingly, the life of the battery may be predicted based on the correlation (1330). For example, the life prediction module 160 of FIG. 4 may predict the life of the battery based on the calculated correlation.

According to embodiments, predicting the life of the battery cell (1330) may include predicting a state of health (SOH) of the battery according to the number of charge/discharge cycles based on the cumulative slippage. Then, whether the battery cell is defective may be estimated based on the predicted life of the battery cell (1340). For example, the life estimation module 180 of FIG. 4 may estimate whether the battery cell is defective based on the predicted life of the battery cell.

Although the present disclosure has been described with reference to embodiments and drawings illustrating aspects thereof, the present disclosure is not limited thereto. Various modifications and variations can be made by a person skilled in the art to which the present disclosure belongs within the scope of the technical spirit of the present disclosure.

### DESCRIPTION OF SOME REFERENCE SYMBOLS

1: Battery life estimation system
10: Life estimation device
12: Life estimation data collection device
14: Life prediction device
120: Data generation module
122: CCP calculation module
124: Slippage calculation module
140: Slippage life analysis module
160: Life prediction module
180: Life estimation module
200: Information processing system
210: Memory
220: Processor
230: Communication module
240: Input/output interface
1000: Manufacturing process device
1002: Battery

What is claimed is:

1. A method of estimating a life of a battery, the method comprising:
collecting life estimation data of a battery cell from a manufacturing process device of the battery cell;
calculating slippage-related data based on the life estimation data;
predicting a life of the battery cell based on the calculated slippage-related data; and
estimating a life quality of the battery cell based on the predicted life.

2. The method as claimed in claim 1, wherein predicting the life of the battery comprises:
calculating cumulative slippage data based on the life estimation data of the battery;
calculating a correlation between the cumulative slippage and a performance life of the battery;
predicting the life of the battery based on the correlation; and
estimating whether the battery cell is defective based on the predicted life of the battery cell.

3. The method as claimed in claim 2, wherein the life estimation data comprises voltage profile data on a capacity of the battery after 0 to 250 charge/discharge cycles.

4. The method as claimed in claim 3, wherein the calculating the cumulative slippage data comprises:
calculating cumulative capacity profile data based on the life estimation data; and
calculating the cumulative slippage based on the cumulative capacity profile data.

5. The method as claimed in claim 4, wherein calculating the correlation comprises:
calculating a point of a sudden performance degradation of the battery based on the correlation between the cumulative slippage and the performance life of the battery.

6. The method as claimed in claim 5, wherein each of the plurality of charge profiles is a voltage profile corresponding to the capacity of the battery for one charge cycle, and
wherein each of the plurality of discharge profiles is a voltage profile corresponding to the capacity of the battery for one discharge cycle.

7. The method as claimed in claim 6, wherein calculating the cumulative slippage data further comprises calculating a plurality of charge slippages and a plurality of discharge slippages based on the cumulative capacity profile data.

8. The method as claimed in claim 7, wherein each of the plurality of charge slippages is an amount of change between a charge profile of a first charge cycle and a charge profile of a subsequent charge cycle, and
wherein each of the plurality of discharge slippages is an amount of change between a discharge profile of a first discharge cycle and a discharge profile of a subsequent discharge cycle.

9. The method as claimed in claim 8, wherein calculating the cumulative slippage data further comprises calculating the cumulative slippage based on the plurality of charge slippages and the plurality of discharge slippages.

10. The method as claimed in claim 9, wherein the cumulative slippage is a sum of differences between each of the charge slippages and each of the discharge slippages.

11. The method as claimed in claim 10, wherein predicting the life of the battery cell comprises calculating a point of a sudden performance degradation of the battery based on the correlation between the cumulative slippage and the performance life of the battery.

12. The method as claimed in claim 11, wherein the predicting the life of the battery cell further comprises calculating a correlation between the cumulative slippage and the performance life of the battery using a linear regression model.

13. The method as claimed in claim 12, wherein the predicting the life of the battery cell further comprises predicting a state of health of the battery according to charge/discharge cycles based on the point of a sudden performance degradation.

14. A system for estimating a life of a battery, the system comprising:
a life estimation data collection device configured to collect life estimation data of a battery cell from a manufacturing process device that manufactures the battery cell; and
a life prediction device configured to:
calculate slippage-related data based on the life estimation data,
predict a life of the battery cell based on the calculated slippage-related data, and
estimate a life quality of the battery cell based on the predicted life.

15. The system as claimed in claim 14, wherein the life prediction device comprises at least one processor configured to read out and execute instructions stored in a memory to cause the life prediction device to function as:
a data generation module configured to generate cumulative slippage data based on the life estimation data of the battery;
a slippage life analysis module configured to calculate a correlation between the cumulative slippage and a performance life of the battery;
a life prediction module configured to predict the life of the battery based on the correlation; and
a life estimation module configured to estimate whether the battery cell is defective based on the predicted life of the battery cell.

16. The system as claimed in claim 15, wherein the life estimation data comprises voltage profile data on a capacity of the battery after 0 to 250 charge/discharge cycles.

17. The system as claimed in claim 16, wherein the data generation module comprises:
a cumulative capacity profile calculation module configured to calculate cumulative capacity profile data based on the life estimation data; and
a slippage calculation module configured to calculate a cumulative slippage based on the cumulative capacity profile data.

18. The system as claimed in claim 17, wherein the cumulative capacity profile generation module is configured to calculate the cumulative capacity profile data based on a plurality of charge profiles and a plurality of discharge profiles extracted from the life estimation data.

19. The system as claimed in claim 18, wherein the life prediction module is configured to predict a state of health of the battery corresponding to charge/discharge cycles based on the point of a sudden performance degradation.

20. The system as claimed in claim 19, wherein the life estimation module is configured to:
compare requirements for the battery cell received from the manufacturing process device with the predicted life of the battery cell; and
estimate whether the battery cell is defective based on the comparison.
